(19) United States
(12) Patent Application Publication
(10) Pub. No.: US 2025/0275083 A1
(43) Pub. Date: Aug. 28, 2025

(54) DUAL OUTLET BLOWER TECHNOLOGY FOR ENHANCED HEAT TRANSFER IN THIN FORM FACTOR DEVICES

(71) Applicant: Advanced Micro Devices, Inc., Santa Clara, CA (US)

(72) Inventors: Pablo HIDALGO ARDANA, Austin, TX (US); Yoshifumi NISHI, Austin, TX (US)

(21) Appl. No.: 18/984,878

(22) Filed: Dec. 17, 2024

Related U.S. Application Data
(60) Provisional application No. 63/559,013, filed on Feb. 28, 2024.

(51) Int. Cl. H05K 7/20; G06F 1/20

(52) U.S. Cl. CPC H05K 7/20172; G06F 1/206; H05K 7/20145; G06F 2200/201; H05K 7/20154

(57) ABSTRACT

Disclosed herein are blower fans, a computing device having blower fans, and a method for operating a computing device having blower fans. The blower fans described herein include blower fans having one air outlet and blower fans having two (e.g., dual) air outlets. In one example, the blower fan includes at least one outlet that is configured to direct air between an electronic device and a housing of the computing device, thus mitigating hot spots direct adjacent the electronic device.

### CROSS REFERENCE TO RELATED APPLICATIONS

This application claims benefit of U.S. Provisional Application Ser. No. 63/559,013, filed Feb. 28, 2024, which is incorporated by reference in its entirety.

### TECHNICAL FIELD

Embodiments of the disclosure generally relate to blower fans suitable for use in computing devices, and computing devices having the same. More particularly, some embodiments of the disclosure relate to dual outlet blower fans and computing devices having the same.

### BACKGROUND

Today's mobile devices must meet strict skin temperature limit for safety, ergonomics and user experience (UX). Adding to these challenges, end users have also come to expect lower temperature ergonomics over the years despite the increased heat flux from the processor and increased power support to allow novel experiences like AI to be run locally in local computing device (such as Edge computing) in mobile computing devices, such as laptops, tablets, mobile phones and the like. Almost all OEMs are implementing mechanisms for steady-state power reduction control in their mobile computing devices to meet such skin temperature limits. Furthermore, with ever shrinking thickness of mobile computing devices, it is becoming increasingly more difficult to assure mechanical reliability of the cooling fans used in these devices.

Some known techniques for improved cooling include the use of high conductivity heat spreaders (copper foil, graphite sheet) bonded to the bottom skin of the mobile computing device. Auxiliary system cooling fans for active internal cooling have also been utilized, along with pressurized airflow inside the chassis of the mobile computing device and heat pipes. However, these techniques have not completely quenched the need for improved cooling.

Thus, there remains a need for improved cooling for computing devices.

### SUMMARY

Disclosed herein are blower fans, a computing device having blower fans, and a method for operating a computing device having blower fans. The blower fans described herein include blower fans having one air outlet and blower fans having two (e.g., dual) air outlets. In one example, the blower fan includes at least one outlet that is configured to direct air between an electronic device and a housing of the computing device, thus mitigating hot spots direct adjacent the electronic device.

In one example, a blower fan is provided. The blower fan includes a fan blade disposed in an interior volume of a housing. The housing includes a first cover, a second cover, a first side and a second side. The first and second covers and the first and second sides partially bound the interior volume of the housing in which the fan blade is disposed. The first cover has an air inlet formed therethrough. The housing has a first air outlet defined through the first side. The housing has a second air outlet defined through one or both of the second side and the first cover. The first air outlet is configured to predominantly direct air in a direction substantially parallel with a plane of the first cover, while the second air outlet is configured to direct air in a direction forming an obtuse angle with the plane of the first cover.

In another example, computing device is provided. The computing device includes a housing having an interior volume in which an electronic device and blower fan are disposed. The electronic device includes at least one integrated circuit (IC) die. The blower fan includes first cover, a second cover, a first side and a second side. The first and second covers and the first and second sides partially bound an interior volume of the blower fan. The first cover is disposed parallel with and adjacent to a side of the housing. The blower fan has an air inlet is formed through one of the first and second covers, a first air outlet defined through the first side, and a second air outlet defined through one or both of the second side and the one of the first and second covers closest to the side of the housing. The first air outlet is configured to direct air in a direction substantially parallel with a plane of the first cover, while the second air outlet configured to direct air in a direction more directed toward the side of the housing relative to the direction of the air exiting the first air outlet.

In still another example, a method for operating a computing device is provided. The method includes operating one or more integrated circuit (IC) dies of an electronic device disposed in an interior volume of a housing of the computing device; directing air exiting a first air outlet of a blower fan in a direction substantially parallel to a side of the housing; and directing air exiting a second air outlet of a blower fan in a direction more toward the side of the housing relative to the direction of the air exiting the first air outlet, the air exiting the second air outlet directed between the electronic device and the side of the housing.

### BRIEF DESCRIPTION OF DRAWINGS

FIG. 1 is a simplified schematic diagram of a computing device having a dual outlet blower fan.

FIG. 2 depicts an exploded view of a portion of the computing device illustrating the dual outlet blower fan, a heat generating electronic device, and a thermal module.

FIGS. 3 and 4 depict top and bottom views of the dual outlet blower fan illustrated in FIG. 1.

FIG. 5 depicts a side view of the dual outlet blower fan illustrated in FIG. 1.

FIGS. 6 and 7 depict partial sectional views through the sidewalls of the dual outlet blower fan illustrated in FIG. 1.

FIG. 8 depicts a partial sectional view of the computing device illustrating air flow being directed from one outlet of the dual outlet blower fan along a housing of the computing device, according to a first example.

FIG. 9 depicts a partial sectional view of the computing device illustrating air flow being directed from one outlet of the dual outlet blower fan along a housing of the computing device, according to a second example.

FIG. 10 depicts a partial sectional view of the computing device illustrating air flow being directed from one outlet of the dual outlet blower fan along a housing of the computing device, according to a third example.

FIG. 11 depicts a partial sectional view of the computing device illustrating air flow being directed from one outlet of the dual outlet blower fan along a housing of the computing device, according to a fourth example.

FIG. 12 is a block diagram of a method for operating a computing device having a dual outlet blower fan.

FIGS. 13 and 14 depict top and bottom views of a single outlet blower fan.

FIG. 15 depicts a partial sectional view of the computing device illustrating air flow being directed from one outlet of a single outlet blower fan along a housing of the computing device, according to a first example.

FIG. 16 is a top view of a thermally conductive sheet of the single outlet blower fan depicted in FIGS. 13 and 14.

FIG. 17 is a block diagram of a method for operating a computing device having a single outlet blower fan.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Described herein is a unique geometry of blower fans that enable better cooling of the outside surfaces (skin) of a chassis (e.g., case or housing) of computing devices, improved mechanical reliability of the fans, and lower cost of the fan assembly. Both single and dual outlet blower fans are disclosed herein. The unique geometry of the dual outlet blower fan enable mobile and other computing devices to achieve enhanced chassis surface cooling for improved ergonomics and mechanical reliability. In one example, a computing device includes a housing, a thermal module, and a dual outlet blower fan. The thermal module and the dual outlet blower fan are disposed in an interior volume of the housing. The thermal module has a surface disposed in a parallel spaced apart relationship with a skin of the housing. The dual outlet blower fan is oriented to direct flow from a first outlet into the interior volume of the housing while a secondary outlet of the dual outlet blower fan between the thermal module and the skin.

The secondary outlet opening on the blower fan fan's cover faces and/or is over one of the sidewalls such that the flow exiting such opening forms a wall jet that is directed against the system chassis and flow along it. The wall jet has significantly faster velocity as compared to conventional fans, and does not sacrifice significant amount of flow being diverted from the primary outlet of the blower fan, therefore cooling the skin of the computing device more efficiently.

Retaining the sidewall structure of the blower fan (as compared to conventional dual blower fans that have one sidewall removed to accommodate the second outlet) also enables additional mechanical structure for support and can prevent the system chassis from mechanical contact the fan rotor when under a compressive load. Thus, the blower fan disclosed herein has enhanced reliability. Moreover, the reliability improvement is not limited to the blower fans, but rather the disclosed technology improves product level mechanical reliability (since many modern devices consider fans as structural parts).

With the conventional dual outlet blower fan, a part of the frame (i.e., sidewall) needs to be cut to create an opening. This creates structurally weak point and additional reinforcement on the fan covers is typically required. With the present innovation, the frame remains intact therefore structure of the fan is not compromised.

Cut frame of the conventional dual outlet blower fan requires a separate sub-frame to support the covers, thus requiring an additional part and tooling cost. In contrast, the novel dual outlet blower fan eliminates the need for additional parts and lowers the overall cost of the blower fan.

The unique geometry of novel dual outlet blower fan enables better cooling of the outside surfaces (skin or chassis) of computing devices (such as laptops, desktops, servers, controllers, vehicle computing devices, mobile computing devices, smart phones, and the like), improved mechanical reliability of the fans, and lower cost of the fan assembly. Novel features include outlet opening(s) on fan cover(s) or sidewall to introduce a directed wall jet (over the sidewall) that flows along the chassis of the computing device. With conventional dual outlet blower fan pressurizing the system, flow is quickly dispersed and diffused. With the novel dual outlet blower fan, flow “attaches” to the bottom surface of cover wall (i.e., the skin) of the computing device, and retains higher velocity without losing significant portion of airflow to the primary heatsink, (i.e., thermal module). This result in significantly more efficient cooling of the chassis and of the electronic device.

In one example, a computing device includes a housing, a thermal module, and a dual outlet blower fan. The thermal module and the dual outlet blower fan are disposed in an interior volume of the housing. The thermal module has a surface disposed in a parallel spaced apart relationship with a skin of the housing. The dual outlet blower fan is oriented to direct flow from a first outlet of the dual outlet blower fan between the thermal module and the skin.

In another example, the dual outlet blower fan of the computing device includes a thermally conductive sheet extending from the housing in the same direction in which air exiting the second air outlet is directed. A single outlet blower fan is disclosed that also beneficially includes a thermally conductive sheet extending from the housing.

In another example, the dual outlet blower fan of the computing device includes a top cover disposed in a parallel spaced apart relationship with the skin of the housing.

In another example, the top cover further comprises an inlet and a notch, the notch forming the first outlet of the dual outlet blower fan.

In another example, the dual outlet blower fan of the computing device has a first sidewall coupled to the top cover, at least a portion of the sidewall spaced apart from the cover to form the first outlet of the dual outlet blower fan.

In another example, the dual outlet blower fan of the computing device preferentially directs a greater amount of flow from the first outlet of the dual outlet blower fan between a first surface of the thermal module and the skin relative to flow between a second surface of the thermal module that faces a away from the second surface and a chip package.

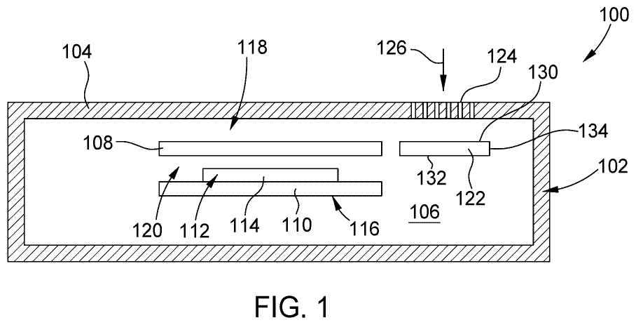

Turning now to FIG. 1, a simplified schematic diagram of a computing device 100 having a dual outlet blower fan 122 is illustrated. The computing device 100 may be embodied a laptop, desktop, server, controller, vehicle computing device, mobile computing device, or a smart phone, among others. The computing device 100 includes a chassis 102 that encloses an interior volume 106. The chassis 102 may also be referred to as an enclosure or housing. The computing device 100 also includes at least one electronic device 116 disposed in the interior volume 106 that is cooled, at least in part, by the dual outlet blower fan 122. Optionally, a thermal module 108 may also be disposed in the interior volume 106 that is utilized to enhance the cooling of the electronic device 116.

The dual outlet blower fan 122 is generally disposed adjacent the skin 104 (i.e., outer surface) of the chassis 102. The skin 104 also includes a plurality of apertures 124 that allow air flow, depicted by arrow 126 in FIG. 1, to enter the interior volume 106 of the computing device 100, where the air is directed by the dual outlet blower fan 122 to facility cooling of the electronic device 116. The apertures 124 may be holes, slots or other passage that facilitates air movement into the interior volume 106 of the chassis 102. In FIG. 1, the dual outlet blower fan 122 is disposed immediately adjacent the plurality of apertures 124 formed through the skin 104 of the chassis 102. Although not shown in FIG. 1, standoffs may be utilized to space the dual outlet blower fan 122 from the skin 104 of the chassis 102.

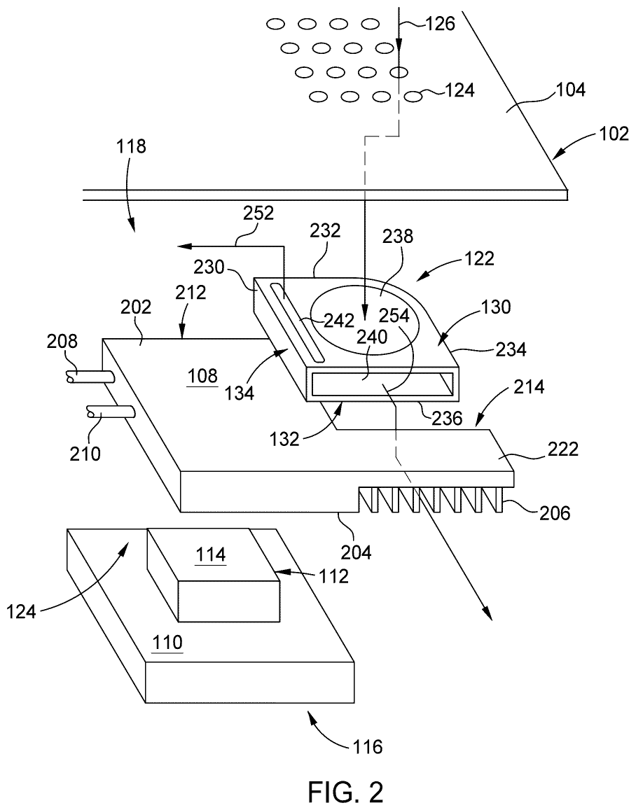

The dual outlet blower fan 122 generally includes a first (i.e., top) cover 130 and a second (i.e., bottom) cover 132 that are coupled by sidewalls 134. The top and bottom covers 130, 132 define the major surfaces of the dual outlet blower fan 122. The top cover 130 includes the inlet of the dual outlet blower fan 122, and is generally spaced below the air inlet apertures 124 of the chassis 102. The top cover 130 may also include one of the outlets of the dual outlet blower fan 122, with the other outlet formed through one of the sidewalls 134, as further illustrated below with respect to FIG. 2.

Continuing to refer to FIG. 1, the electronic device 116 generally includes at least one integrated circuit (IC) die 114. The IC die 114 may be part of a chip package 112 that includes a package substrate and optionally one or more other IC dies. The IC die 114 includes functional circuitry. The functional circuitry of the IC die 114 may be configured to function as a programmable logic device, such as field programmable gate array (FPGA), a memory device, an optical device, a logic device, a processor, a math engine, or other IC logic structures. Optical devices include photo-detectors, lasers, optical sources, and the like.

In one example, the functional circuitry of the IC die 114 may include central processing unit (CPU) cores. As such, the IC die 114 containing CPU cores may be referred to as a CPU die or CPU chiplet. The functional circuitry of the IC die 114 may also include System Management Unit (SMU). The SMU is circuitry configured to monitor thermal and power conditions and adjust power and cooling to keep the IC die 114 functioning as within specifications. The functional circuitry of the IC die 114 may also include Dynamic Function exchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry of IC die 114 includes accelerated compute cores. As such, the IC die 114 containing accelerated compute cores may be referred to as an accelerator die or accelerator chiplet. The IC die 114 containing accelerated compute cores may also be referred to as a graphic processing unit (GPU) die or GPU chiplet. The accelerated compute cores contained in the functional circuitry of the IC die 114 generally includes math engine circuitry. The math engine circuitry is generally designed for task specific computing, such as used data center computing, high performance computing and Al/ML computing. Along with the accelerated compute cores, functional circuitry of the IC die 114 may also include SMU circuitry and DFX circuitry.

The IC die 114 (and/or chip package 112) is mounted to a printed circuit board 110. The printed circuit board 110 may be part of a motherboard, daughter board, expansion card and the like. The printed circuit board 110 and IC die 114 mounted thereon are generally spaced laterally from, and below, the dual outlet blower fan 122 (utilizing the skin 104 that contains the apertures 124 as a point of reference).

The thermal module 108, when present, is disposed between the electronic device 116 and side of the chassis 102 that contains the apertures 124. The thermal module 108 is spaced from the skin 104, thus forming a first air passage 118 defined between the thermal module 108 and the skin 104. The thermal module 108 is also spaced from the IC die 114 of the electronic device 116, thus forming a second air passage 120 defined between the thermal module 108 and the electronic device 116 (i.e., the IC die 114). As later detailed below, air exiting one outlet of the dual outlet blower fan 122 preferentially directs air through the first air passage 118 relative to the second air passages 120, which enhances heat transfer between the thermal module 108 and skin 104 of the chassis 102, which effectively increases the heat transfer from the electronic device 116 to the chassis 102. The enhanced heat transfer from the IC die 114 of the electronic device 116 to the chassis 102 results in improved performance, reliability and service life of the IC die 114, and consequently, improved performance, reliability and service life of the computing device 100.

FIG. 2 depicts an exploded view of a portion of the computing device 100 illustrating the dual outlet blower fan 122, the electronic device 116, and the thermal module 108. The thermal module 108 generally includes a body 212 formed from a metal or other material having high thermal conductivity. The body 212 has a first side 202 that faces the skin 104 of the chassis 102 that includes the air inlet apertures 124. The body 212 has a second side 204 that faces away from the side 202 and toward the electronic device 116. The first side 202 bounds one side of the first air passage 118, while the second side 204 bounds one side of the second air passage 120. In some examples, the body 212 may also include an extension 222 that, with the main portion body 212, forms a notch 214 for receiving the dual outlet blower fan 122.

The thermal module 108 generally functions as a heat sink and or heat exchanger for removing heat generated by the electronic device 116 so that the IC die 114 may be maintained at or below maximum operating temperature. The thermal module 108 also provides the electronic device 116 from creating hots spots in the adjacent portions of the skin 104 of the chassis 102. The thermal module 108 may be at least one or both of an active or passive heat transfer device. Examples of active heat transfer devices includes thermoelectric coolers, forced air heat exchangers, forced liquid heat exchangers, and the like. Examples of passive heat transfer devices includes vapor chambers, heat pipes, phase change materials, fins, and the like. In the example depicted in FIG. 1, the thermal module 108 includes fins 206 and one or more internal passages (not shown) coupled to a coolant inlet 208 and coolant outlet 210 for circulating a coolant within the body 212 of the thermal module 108.

As briefly described above, the dual outlet blower fan 122 includes top and bottom covers 130, 132 coupled by sidewalls 134. The top and bottom covers 130, 132 are, in one example, parallel to a plane defined by the skin 104 of the chassis 102 that contains the air inlet apertures 124. The dual outlet blower fan 122 is generally rectangular in shape, having first, second, third and fourth sides 230, 232, 234, 236.

The dual outlet blower fan 122 generally has a first air outlet 240 formed in one of the sides 230, 232, 234, 236 of the dual outlet blower fan 122. The first side 230 of the dual outlet blower fan 122 is oriented to generally face in the direction of the electronic device 116. In FIG. 2, the first air outlet 240 formed in the fourth side 236 of the dual outlet blower fan 122. Air (illustrated by arrow 254) exiting the first air outlet 240 of the dual outlet blower fan 122 is predominantly directed in a direction parallel to the plane defined by the skin 104 of the chassis 102 that contains the air inlet apertures 124. The first air outlet 240 is oriented facing the extension 222 of the body 212 of the thermal module 108 such that air exiting the first air outlet 240 of the dual outlet blower fan 122 is directed across the fins 206 extending from the thermal module 108. The first air outlet 240 may optionally also have an orientation not direct facing the electronic device 116, such that air exiting the first air outlet 240 of the dual outlet blower fan 122 is directed away from (i.e., not in direct contact with) the electronic device 116.

A second air outlet 242 of the dual outlet blower fan 122 is generally formed another one of the sides 230, 232, 234, 236 and/or the top cover 130 of the dual outlet blower fan 122. In FIG. 2, the first air outlet 240 formed through the top cover 130 generally adjacent to the first side 230 of the dual outlet blower fan 122. As the first dies 130 of the dual outlet blower fan 122 is adjacent the fourth side 136 of the dual outlet blower fan 122, the direction of air (illustrated by arrow 252) exiting the second air outlet 242 is substantially perpendicular to the direction of the air (illustrated by arrow 254) exiting the first air outlet 240 of the dual outlet blower fan 122 when viewed in a direction perpendicular to the plane of the top cover 130. The air exiting the second air outlet 240 of the dual outlet blower fan 122 also is directed at an angle more towards the skin 104 of the chassis 102 that contains the air inlet apertures 124 relative to the air exiting the first air outlet 240 of the dual outlet blower fan 122. Thus, air exiting the second air outlet 240 of the dual outlet blower fan 122 is directed at an obtuse angle relative to the plane of the top cover 130, and predominantly directed through the first air passage 118 relative to the second air passage 120 such that that transfer between the thermal module 108 and skin 104 of the chassis 102 is enhanced, ultimately improving thermal management of the temperature of the IC die 114.

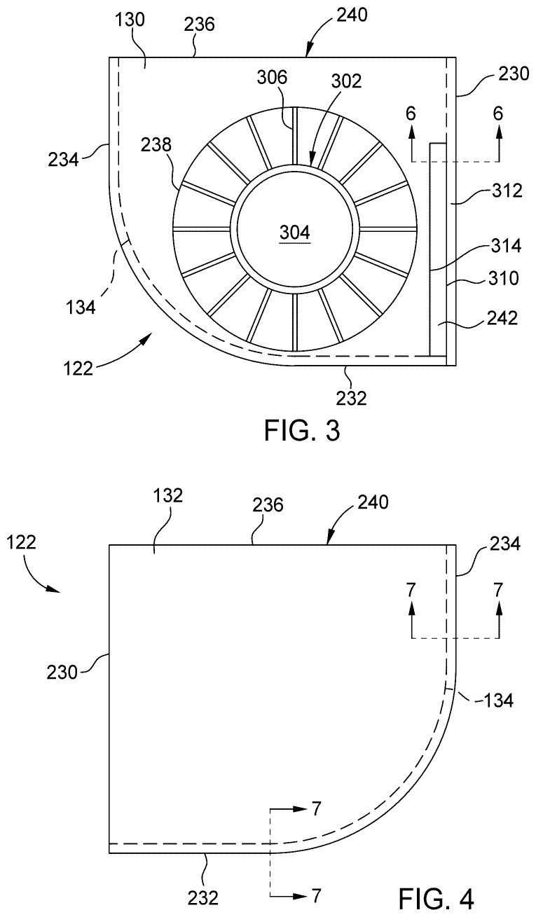

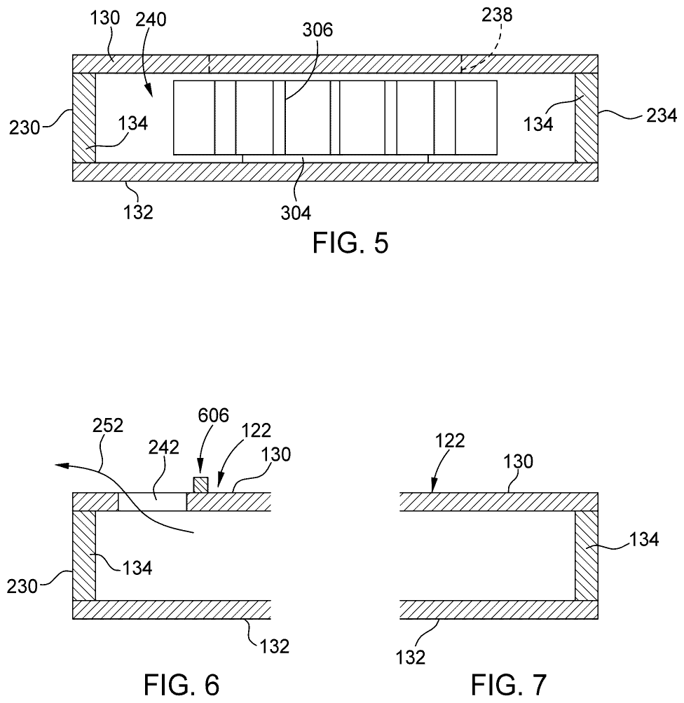

FIGS. 3 and 4 depict top and bottom views of the dual outlet blower fan 122 illustrated in FIGS. 1 and 2. The dual outlet blower fan 122 generally includes a motor 304 that rotates a rotor 302. The motor 304 may a brushless DC or other suitable electric motor. Fan blades 306 are coupled to the rotor 302 such that as the rotor 302 and fan blades 306 are spun by the motor 304, air is drawn into the dual outlet blower fan 122 through the air inlet 238 formed through the top cover 130, and forced out of the dual outlet blower fan 122 through the two air outlets 240, 242 as described above. In one example and as additionally illustrated in FIG. 5, the first air inlet 240 is formed on the fourth side 236 of the dual outlet blower fan 122. In the example illustrated in FIG. 5, the first air inlet 240 spans the entire fourth side 236 of the dual outlet blower fan 122, being bounded by the sidewalls 134 present on the first and third sides 130, 134.

Referring now to FIG. 3, the second air outlet 242 is formed along the first side 230 of the dual outlet blower fan 122. The second air outlet 242 may span the entire first side 230 of the dual outlet blower fan 122 or only a portion of the first side 230 of the dual outlet blower fan 122. In FIG. 3, the first side 230 of the dual outlet blower fan 122 extends from the second side 232 of the dual outlet blower fan 122 and terminates a distance further from the fourth side 236 of dual outlet blower fan 122 than a distance that the air inlet 238 is spaced from the fourth side 236. Stated differently, the second air outlet 242 may span a distance less than half or more than half of a distance defined between the first side 230 and an opposite side (e.g., the third side 234) of the housing (e.g., chassis 102).

As illustrated in FIG. 3, the second air outlet 242 is formed entirely in the top cover 130. In one example, the second air outlet 242 may be formed as a slot 310 formed in the top cover 130, wherein a web 312 of material of the top cover 130 separates the second air outlet 242 from the first side 230 of the dual outlet blower fan 122. In another example, the second air outlet 242 may be formed as a notch 314 formed in the top cover 130 that is open to the sidewall 134 extending across the first side 230 of the dual outlet blower fan 122. Alternatively, the second air outlet 242 may be formed in one or both of the sidewall 134 and top cover 130 in a manner that directs air towards the skin 104 of the chassis 102.

FIGS. 6 and 7 depict partial sectional views through the sidewalls of the dual outlet blower fan 122 illustrated in FIGS. 4 and 5. In FIG. 6, the second air outlet 242 is shown formed at least partially through the top cover 130. Optionally, a portion of the second air outlet 242 may be formed at least partially through the sidewall 134 spanning the first side 230 of the dual outlet blower fan 122. The top cover 130 may optionally have a projection 606, such as a ridge, extending between the second air outlet 242 and the air inlet 238 to help direct the air flow (252) in a direction away from the air inlet 238 and into the passage 118 between the thermal module 108 and skin 104 of the chassis 102.

FIG. 7 generally depicts that the sidewall 134 spanning the second and third sides 232, 234 of the dual outlet blower fan 122 connects the top and bottom covers 130, 132.

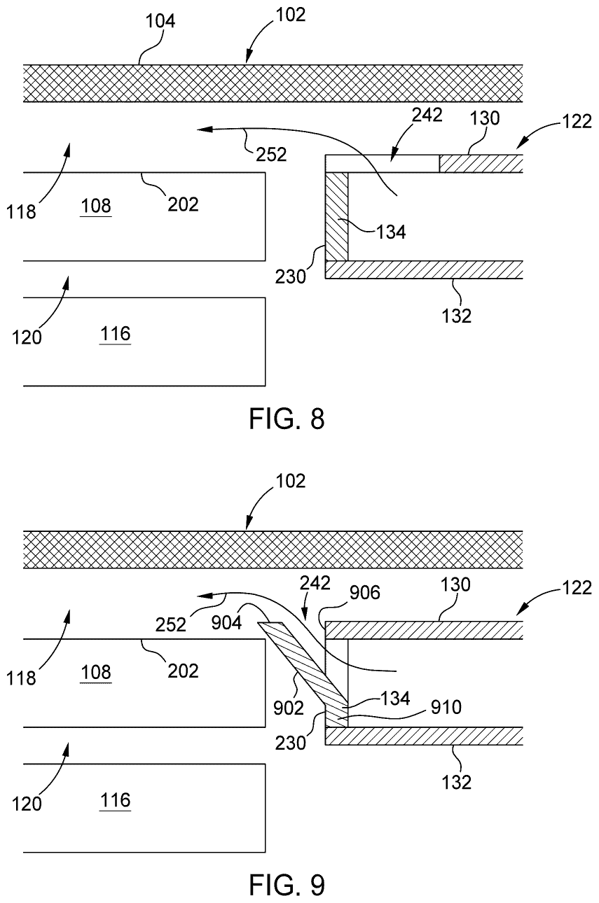

FIG. 8 depicts a partial sectional view of the computing device 100 illustrating air flow 242 being directed from one outlet 242 of the dual outlet blower fan 122 between the skin 104 of the chassis 102 of the computing device 100, according to a first example as initially discussed above. As the air flow 242 exiting the second outlet 242 of the dual outlet blower fan 122 has a directional vector towards the skin 104, the air flow 242 is predominantly directed through the first passage 118 defined between the chassis 102 and top surface 202 of the thermal module 108 relative to the second passage 120 defined between the bottom surface 204 of the thermal module 108 and the electronic device 116.

FIG. 9 depicts a partial sectional view of the computing device 100 illustrating air flow 242 being directed from the second outlet 242 of the dual outlet blower fan 122 between the skin 104 of the chassis 102 of the computing device 100, in an example where the second outlet 242 is at least partially formed in the sidewall 134 spanning the first side 230 of the dual outlet blower fan 122. The second outlet 242 may optionally be also formed in a portion of the top cover 130.

In the example depicted in FIG. 9, the sidewall 134 spanning the first side 230 of the dual outlet blower fan 122 includes a flared portion 902. The flared portion 902 extends from a portion 910 of the sidewall 134 connected to the bottom cover 132. The flared portion 902 extends to a distal end 904. The distal end 904 of the flared portion 902 is spaced from an edge 906 of the top cover 130, creating an aperture therebetween that forms the second outlet 242 of the dual outlet blower fan 122. The upwardly and outwardly orientation of the flared portion 902 helps direct the air 252 exiting the second outlet 242 in a direction towards the skin 104 of the chassis 102 and away from the dual outlet blower fan 122, and consequently predominantly into the first air passage 118 relative to the second air passage 120.

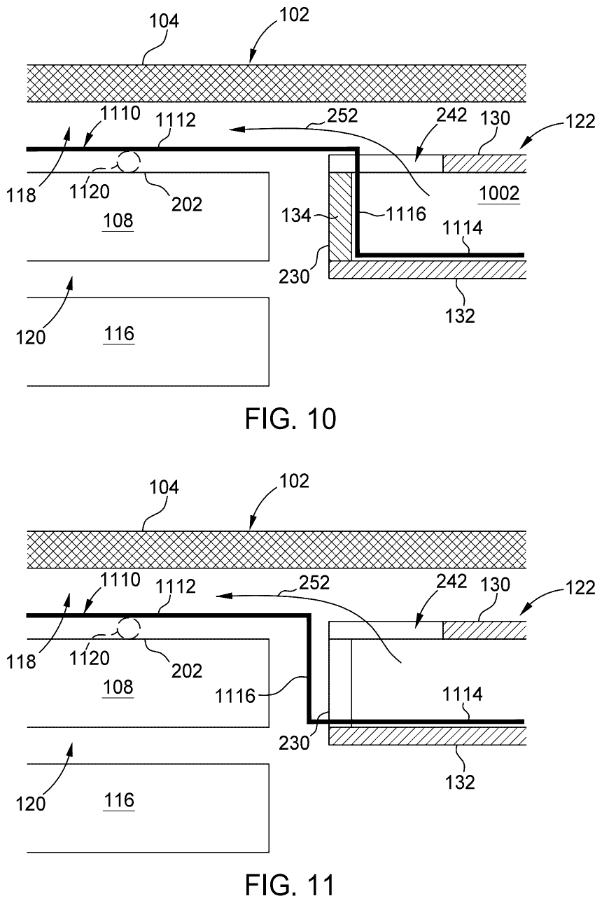

FIG. 10 depicts a partial sectional view of the computing device 100 illustrating air flow 242 being directed from one outlet 242 of the dual outlet blower fan 122 between the skin 104 of the chassis 102 of the computing device 100, according to another example. In the example depicted in FIG. 10, the dual outlet blower fan 122 includes a thermally conductive sheet 1110. The thermally conductive sheet 1110 may be fabricated from graphite, metal sheet, metal foil, or other suitable highly thermally conducive material. The thermally conductive sheet 1110 includes a first portion 1112 that is outside of the dual outlet blower fan 122 and a second portion 1114 that is disposed within the dual outlet blower fan 122. The first portion 1112 extends from the first side 230 of the dual outlet blower fan 122 into the region between the thermal module 108 and skin 104 of the chassis 102. The first portion 1112 of the thermally conductive sheet 1110 may bound the first air passage 118 with the skin 104 of the chassis 102. The first portion 1112 of the thermally conductive sheet 1110 may be freely disposed adjacent the thermal module 108, or may be connected to the thermal module 108 via a thermal interface 1120. The thermal interface 1120 may be comprises of one or more of thermal interface materials (TIM), heat pipe, solder, brazing material or other material and/or device that enhances the transfer of heat between the thermal module 108 and the conductive sheet 1110.

The conductive sheet 1110 functions to increase the heat transfer across the passage 118 to the skin 104 of the chassis 102. The conductive sheet 1110 also functions to conduct heat from first portion 1112 outside of the dual outlet blower fan 122 to second portion 1114 of the conductive sheet 1110 disposed within the dual outlet blower fan 122. As the second portion 1114 of the conductive sheet 1110 disposed within the dual outlet blower fan 122 is exposed to higher air velocities, heat is more readily transferred from the second portion 1114 of the conductive sheet 1110 to the air within the dual outlet blower fan 122, where the heat transferred to the air is rapidly expelled with the air exiting the dual outlet blower fan 122 through the two outlets 240, 242.

The first and second portions 1112, 1114 of the conductive sheet 1110 may in one example be coplanar. In another example first and second portions 1112, 1114 of the conductive sheet 1110 reside in parallel planes. The conductive sheet 1110 may, but is not required, to extend through the second outlet 242.

In the example depicted in FIG. 10, the first and second portions 1112, 1114 of the conductive sheet 1110 are connected by an intermediate portion 1116. The intermediate portion 1116 may form a step connecting the first and second portions 1112, 1114. The intermediate portion 1116 may have an orientation that is perpendicular to at least one of the first and second portions 1112, 1114 of the conductive sheet 1110 and/or the top cover 130. Optionally, the intermediate portion 1116 may have an orientation that is flared upward and outward from the second portion 1114 to the first portion 1112 such that air 252 exiting the second outlet 242 is directed towards the skin 104 of the chassis 102, and predominantly through the first air passage 118 relative to the second air passage 120.

FIG. 11 depicts a partial sectional view of the computing device 100 illustrating air flow being directed from one outlet 242 of the dual outlet blower fan 122 along a chassis 102 of the computing device 100, according to a fourth example. Similar to the dual outlet blower fan 122 described with reference to FIG. 10, the dual outlet blower fan 122 depicted in FIG. 11 includes a thermally conductive sheet 1110, except in that the second outlet 242 through which the thermally conductive sheet 1110 extends includes some or all of the first side 230 of the dual outlet blower fan 122. Although the intermediate portion 1116 of the thermally conductive sheet 1110 illustrated in FIG. 11 has an orientation that is perpendicular to at least one of the first and second portions 1112, 1114, the intermediate portion 1116 may optionally have an orientation that is flared upward and outward from the second portion 1114 to the first portion 1112 such that air 252 exiting the second outlet 242 is directed towards the skin 104 of the chassis 102, and predominantly through the first air passage 118 relative to the second air passage 120.

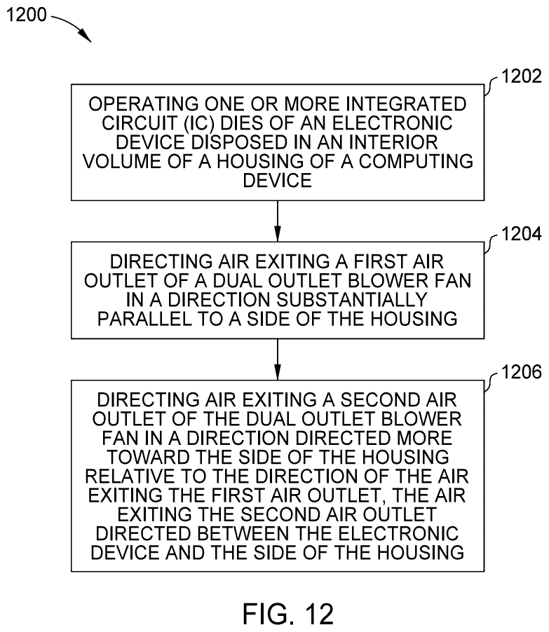

FIG. 12 is a block diagram of a method 1200 for operating a computing device, such as but not limited to the computing device 100 described above. The method 1200 begins a operation 1202 by operating one or more integrated circuit (IC) dies 114 of an electronic device 116 disposed in an interior volume 106 of a housing (e.g., chassis 102) of a computing device 100. Operating the IC dies 114 may include preforming logic processing, training models, performing computations, reading from memory, writing to memory, or other operation generally able to be performed by the functional circuitry of an integrated circuit die.

At operation 1204, air exiting a first air outlet 240 of the dual outlet blower fan 122 is directed in a direction substantially parallel to a side of the housing (e.g., the chassis 102). For example, air exiting the first air outlet 240 of the dual outlet blower fan 122 is directed in a direction substantially parallel to the skin 104 of a chassis 102 of the computing device 100 that includes the air inlet apertures 124. Air exiting the first air outlet 240 of the dual outlet blower fan 122 may also be directed across fins of a thermal module 108 disposed next to the dual outlet blower fan 122.

At operation 1206, air exiting a second air outlet 242 of the dual outlet blower fan 122 is directed in a direction more toward the side of the housing relative to the direction of the air exiting the first air outlet 240, the air exiting the second air outlet 242 directed between the electronic device and the side of the housing. At operation 1206, air exiting the second air outlet 242 is predominantly directed through a passage defined between the skin of the chassis and a thermal device relative to a passage defined between the thermal device and the electronic device.

The method 1200 may also include directing air out an opening disposed in a first cover of the dual outlet blower fan facing the housing and facing away from the electronic device.

The method 1200 may also include directing air between a conductive sheet extending from the dual outlet blower fan and the side of the housing.

The method 1200 may also include flowing air within the dual outlet blower fan across a portion of the conductive sheet disposed with the dual outlet blower fan.

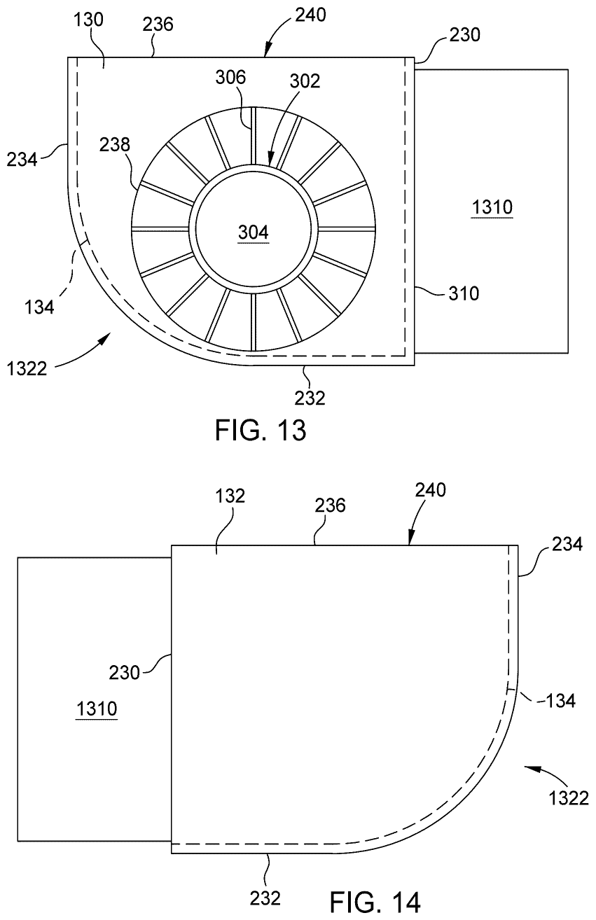

FIGS. 13 and 14 depict top and bottom views of a single outlet blower fan 1322. The single outlet blower fan 1322 may replace the dual outlet blower fan 122 in the computing device 100 described above. The single outlet blower fan 1322 is generally configured the same as any of the dual outlet blower fans 122 described above that include a thermally conductive sheet, except that the second outlet 242 is not present in the single outlet blower fan 1322. The air outlet 240 of the single outlet blower fan 1322 is generally formed through one of the sides of the single outlet blower fan 1322, with the other sides enclosed by the sidewalls 134. In the example depicted in FIGS. 13 and 14, the air outlet 240 is formed through the fourth side 236 of the single outlet blower fan 1322, with the other sides 230, 232, 234 of the single outlet blower fan 1322 are enclosed by the sidewalls 134.

The single outlet blower fan 1322 includes a thermally conductive sheet 1310 that extends outward from one of the sides of the single outlet blower fan 1322. In the example depicted in FIGS. 13 and 14, the thermally conductive sheet 1310 extends from the first side 230 of the single outlet blower fan 1322.

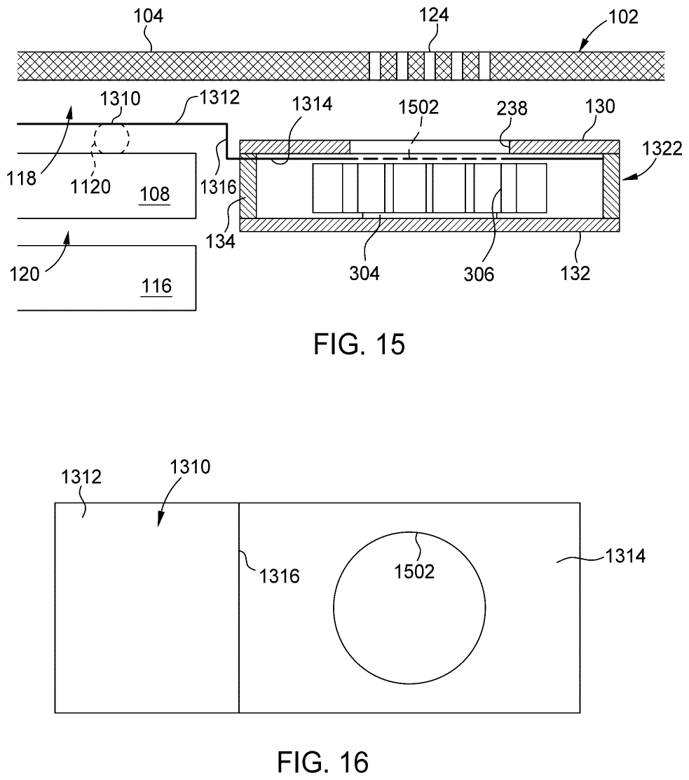

FIG. 15 depicts a partial sectional view of the computing device 100 illustrating air flow being directed from the outlet 240 of the single outlet blower fan 1322 along a skin 104 of the computing device 100, according to a first example. The thermally conductive sheet 1310 may be fabricated from graphite, metal sheet, metal foil, or other suitable highly thermally conducive material.

The thermally conductive sheet 1310 includes a first portion 1312 that is outside of the single outlet blower fan 1322 and a second portion 1314 that is disposed within the single outlet blower fan 1322. The first portion 1312 extends from the first side 230 of the single outlet blower fan 1322 into the region between the thermal module 108 and skin 104 of the chassis 102. The first portion 1312 of the thermally conductive sheet 1310 may bound the first air passage 118 with the skin 104 of the chassis 102. The first portion 1312 of the thermally conductive sheet 1310 may be freely disposed adjacent the thermal module 108, or may be connected to the thermal module 108 via a thermal interface 1120. The thermal interface 1120 may be comprises of one or more of thermal interface materials (TIM), heat pipe, solder, brazing material or other material and/or device that enhances the transfer of heat between the thermal module 108 and the conductive sheet 1310.

The conductive sheet 1310 functions to increase the heat transfer across the passage 118 to the skin 104 of the chassis 102. The conductive sheet 1310 also functions to conduct heat from first portion 1312 outside of the single outlet blower fan 1322 to second portion 1314 of the conductive sheet 1310 disposed within the single outlet blower fan 1322. Since the first portion 1312 resides over the portion of the thermal module 108 closest to the IC die 114, heat readily moves from the IC die 114 through the thermal module 108 to first portion 1312 of the conductive sheet 1310 and then to the second portion 1314 of the conductive sheet 1310. As the second portion 1314 of the conductive sheet 1310 disposed within the single outlet blower fan 1322 is exposed to higher air velocities, heat is more readily transferred from the second portion 1314 of the conductive sheet 1310 to the air within the single outlet blower fan 1322, where the heat transferred to the air is rapidly expelled with the air exiting the single outlet blower fan 1322 through the outlet 240 way from the electronic device 116. Thus, the conductive sheet 1310 prevents hot spots from forming in the skin 104 of the chassis 102 that is closely adjacent the electronic device 116.

The first and second portions 1312, 1314 of the conductive sheet 1310 may, in one example, be coplanar. In another example, the first and second portions 1312, 1314 of the conductive sheet 1310 reside in parallel planes. The conductive sheet 1310 may, but is not required to, extend through the second outlet 242.

In the example depicted in FIG. 10, the first and second portions 1312, 1314 of the conductive sheet 1310 are connected by an intermediate portion 1316. The intermediate portion 1316 may form a step connecting the first and second portions 1312, 1314. The intermediate portion 1316 may have an orientation that is perpendicular to at least one of the first and second portions 1312, 1314 of the conductive sheet 1310 and/or the top cover 130. Optionally, the intermediate portion 1316 may have an orientation that is flared upward and outward from the second portion 1314 to the first portion 1312.

The second portion 1314 of the conductive sheet 1310 may be secured to the bottom surface of the top cover 130 above the blades 306 of the single outlet blower fan 1322. The second portion 1314 of the conductive sheet 1310 may be secured to the bottom surface of the top cover 130 using adhesives, fasteners, staking or other suitable technique. When second portion 1314 is disposed between the fan blades 306 and the air inlet 238 formed through the top cover 130, the second portion 1314 includes an aperture 1502 to facilitate the flow of air from the air inlet 238 to the fan blades 306, and ultimately out of the outlet 240. The aperture 1502 in the second portion 1314 of the conductive sheet 1310 is more clearly depicted in the top view of the thermally conductive sheet 1310 illustrated in FIG. 16.

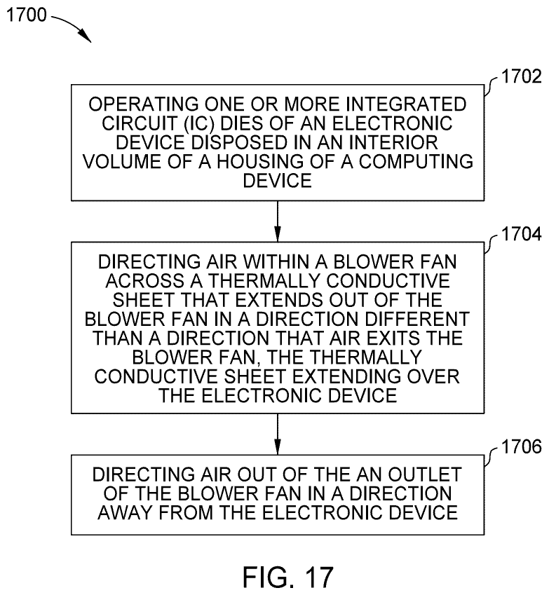

FIG. 17 is a block diagram of a method 1700 for operating for operating a computing device, such as but not limited to the computing device 100 described above. The method 1200 begins a operation 1702 by operating one or more integrated circuit (IC) dies 114 of an electronic device 116 disposed in an interior volume 106 of a housing (e.g., chassis 102) of a computing device 100. Operating the IC dies 114 may include preforming logic processing, training models, performing computations, reading from memory, writing to memory, or other operation generally able to be performed by the functional circuitry of an integrated circuit die.

At operation 1704, air entering the single outlet blower fan 1322 is directed across a thermally conductive sheet 1310 disposed in the interior of the single outlet blower fan 1322. The thermally conductive sheet 1310 extend out of the single outlet blower fan 1322 in a direction different than a direction that air exits the single outlet blower fan 1322. The thermally conductive sheet 1310 extends over the electronic device 116. The thermally conductive sheet 1310 also extends over the thermal module 108.

At operation 1706, air is directed out of an air outlet 240 of the single outlet blower fan 1322 in a direction away from the electronic device 116. In one example, the direction that the thermally conductive sheet 1310 extends away from single outlet blower fan 1322 is substantially perpendicular or opposite to a direction that air is directed out of the outlet 240 of the single outlet blower fan 1322.

Thus, the blower fans and computing devices described herein provide a beneficial alternative to conventional blower fans. The dual outlet blower fans disclosed herein have fewer parts and thus are more cost effective to fabricate, and also have increased structural integrity advantageously suitable for today's higher aspect ratio (shorter but wider) fan designs. The increase rigidity of the cooling fans described herein also results in improved system level mechanical reliability, and allows re-use of a chassis designed for most other cooling technologies without modifications.

While the foregoing is directed to embodiments of the present disclosure, other and further embodiments may be devised without departing from the basic scope thereof, and the scope thereof is determined by the claims that follow.

What is claimed is:

1. A blower fan comprising:
a plurality of fan blades operably coupled to a motor; and
a housing having a first cover, a second cover, a first side and a second side, the first and second covers and the first and second sides partially bounding an interior volume of the housing, the first cover having an air inlet formed therethrough, the housing having a first air outlet defined through the first side, the housing having a second air outlet defined through one or both of the second side and the first cover, the first air outlet configured to direct air in a direction substantially parallel with a plane of the first cover, and the second air outlet configured to direct air in a direction forming an obtuse angle with the plane of the first cover.

2. The blower fan of claim 1, wherein the second side includes a sidewall extending from the second cover towards the first cover, the second air outlet defined between an edge of the sidewall and the first cover.

3. The blower fan of claim 2, wherein a portion of the sidewall meets the first cover, the second air outlet defined in a notch formed in the sidewall.

4. The blower fan of claim 1, wherein first cover includes an opening that defines the second air outlet.

5. The blower fan of claim 4, wherein opening extends half or less than a distance defined between the first side and an opposite side of the housing.

6. The blower fan of claim 4, wherein opening extends half or more than a distance defined between the first side and an opposite side of the housing.

7. The blower fan of claim 1, wherein the first and second sides are adjacent to one another.

8. The blower fan of claim 1 further comprising:
a thermally conductive sheet extending from the housing in a common direction that the second air outlet is oriented to direct air exiting the second air outlet.

9. The blower fan of claim 8, wherein the thermally conductive sheet is exposed to and extends at least partially across the interior volume of the housing.

10. A computing device comprising:
a housing;
an electronic device comprising at least one integrated circuit (IC) die disposed in an interior volume of the housing; and
a blower fan disposed in the interior volume of the housing, the blower fan comprising:
a first cover, a second cover, a first side and a second side, the first and second covers and the first and second sides partially bounding an interior volume of the blower fan, the first cover disposed parallel with and adjacent to a side of the housing;
an air inlet formed through one of the first and second covers;
a first air outlet defined through the first side; and
a second air outlet defined through one or both of the second side and the one of the first and second covers closest to the side of the housing, the first air outlet configured to direct air in a direction substantially parallel with a plane of the first cover, and the second air outlet configured to direct air in a direction more toward the side of the housing relative to the direction of air exiting the first air outlet.

11. The computing device of claim 10, wherein the second side includes a sidewall extending from the second cover towards the first cover, the second air outlet defined between an edge of the sidewall and the first cover.

12. The computing device of claim 11, wherein a portion of the sidewall meets the first cover, the second air outlet defined in a notch formed in the sidewall.

13. The computing device of claim 10, wherein first cover includes an opening that defines the second air outlet.

14. The computing device of claim 10 further comprising:
a thermal management device disposed between the electronic device and a sidewall of the housing, wherein the second air outlet directs air between the side of the housing and the thermal management device.

15. The computing device of claim 14 further comprising:
a thermally conductive sheet extending from the blower fan between the side of the housing and the thermal management device, wherein the second air outlet directs air between the side of the housing and the thermally conductive sheet.

16. The computing device of claim 15, wherein the thermally conductive sheet is exposed to and extends at least partially across the interior volume of the blower fan.

17. A method for operating a computing device having a dual outlet blower fan, the method comprising:
operating one or more integrated circuit (IC) dies of an electronic device disposed in an interior volume of a housing of the computing device;
directing air exiting a first air outlet of the dual outlet blower fan in a direction substantially parallel to a side of the housing; and
directing air exiting a second air outlet of the dual outlet blower fan in a direction more toward the side of the housing relative to the direction of the air exiting the first air outlet, the air exiting the second air outlet directed between the electronic device and the side of the housing.

18. The method of claim 17, wherein directing air exiting the second air outlet further comprises:
directing air out an opening disposed in a first cover of the dual outlet blower fan facing the housing and facing away from the electronic device.

19. The method of claim 17, wherein directing air exiting the second air outlet further comprises:
directing air between a conductive sheet extending from the dual outlet blower fan and the side of the housing.

20. The method of claim 19 further comprising flowing air within the dual outlet blower fan across a portion of the conductive sheet disposed with the dual outlet blower fan.
